(19) United States
(12) Patent Application Publication
(10) Pub. No.: US 2016/0079034 A1
(43) Pub. Date: Mar. 17, 2016

(54) FLOWABLE FILM PROPERTIES TUNING USING IMPLANTATION

(71) Applicant: Applied Materials Inc., Santa Clara, CA (US)

(72) Inventors: Ellie Y. Yieh, San Jose, CA (US); Ludovic Godet, Sunnyvale, CA (US); Jun Xue, San Jose, CA (US); Srinivas D. Nemani, Sunnyvale, CA (US); DongQing (Karen) Li, Fremont, CA (US); Erica Chen, Cupertino, CA (US)

(21) Appl. No.: 14/485,505

(22) Filed: Sep. 12, 2014

(51) Int. Cl. H01J 37/317

(52) U.S. Cl. CPC H01J 37/3171

(57) ABSTRACT

Species are supplied to a flowable layer over a substrate. A property of the flowable layer is modified by implanting the species to the flowable layer. The property comprises a density, a stress, a film shrinkage, an etch selectivity, or any combination thereof.

### FIELD

Embodiments of the present invention pertain to the field of electronic device manufacturing, and in particular, to modifying a property of a dielectric layer.

### BACKGROUND

Dielectric materials are broadly used in the semiconductor industry to produce electronic devices of an ever-decreasing size. Generally, the dielectric material is used as a gap-fill film, a shallow trench insulation (STI), a via fill, a mask, a gate dielectric, or as other electronic device feature.

Generally, silicon dioxide (SiO₂) is a dielectric material. Typically, the SiO₂ deposited using a chemical vapor deposition (CVD) process that is used as a gap fill film has a poor density (about 1.5 g/cm³). Currently, two curing processes, an ozone curing process and a steam anneal process at 500 degrees C. are used to improve the deposited film density. However, these two extra processes induce technical challenges. The steam anneal process has pattern density dependency. Typically, the density of the SiO₂ film after being cured by the steam anneal process in an open (ISO) area of the pattern is higher than in a dense area of the pattern. This uneven film quality leads to very different etch results across different pattern areas.

Furthermore, the 500 degree C. steam anneal induces the film shrinkage and increases film stress. Different film densities and stress between the ISO area and dense area of the pattern introduce dramatic loading effect in etch. Especially in the dense pattern area, the high stress usually results in cracking, peeling of the film, or both. Furthermore, the film shrinkage and high film stress significantly hinder the dielectric film in deep trench and via fill and other applications.

### SUMMARY

Methods and apparatuses to tune a property of a flowable layer are described. In one embodiment, species are supplied to a flowable layer over a substrate. A property of the flowable layer is modified by implanting the species to the flowable layer. The property comprises a density, a stress, a film shrinkage an etch selectivity, or any combination thereof.

In one embodiment, species are supplied to a flowable layer over a substrate. A property of the flowable layer is modified by implanting the species to the flowable layer. The property comprises a density, a stress, a film shrinkage, an etch selectivity, or any combination thereof. The flowable layer acts as an insulation fill layer, a hard mask layer, or both.

In one embodiment, species are supplied to a flowable layer over a substrate. A property of the flowable layer is modified by implanting the species to the flowable layer. The property comprises a density, a stress, a film shrinkage, an etch selectivity, or any combination thereof. At least one of a temperature, an energy, a dose and a mass of the species is adjusted to control the property of the flowable layer.

In one embodiment, species are supplied to a flowable layer over a substrate. A property of the flowable layer is modified by implanting the species to the flowable layer. The property comprises a density, a stress, a film shrinkage, an etch selectivity, or any combination thereof. The species comprise silicon, hydrogen, germanium, boron, carbon, oxygen, nitrogen, argon, helium, neon, krypton, xenon, radon, arsenic, phosphorous or any combination thereof.

In one embodiment, a plurality of fin structures are formed on a substrate. A flowable layer is filled in between the fin structures. The flowable layer is oxidized. Species are supplied to the flowable layer. A property of the flowable layer is modified by implanting the species to the flowable layer. The property comprises a density, a stress, a film shrinkage, an etch selectivity, or any combination thereof. At least a portion of the modified flowable layer is removed.

In one embodiment, a hard mask layer over a substrate is patterned to form a plurality of trenches. A flowable layer is filled into the plurality of trenches. Species are supplied to the flowable layer. A property of the flowable layer is modified by implanting the species to the flowable layer. The property comprises a density, a stress, a film shrinkage, an etch selectivity, or any combination thereof. After the modifying, the patterned hard mask layer is removed while leaving portions of the flowable layer intact.

In one embodiment, a flowable layer over a substrate is oxidized. Species are supplied to the flowable layer. A property of the flowable layer is modified by implanting the species to the flowable layer. The property comprises a density, a stress, a film shrinkage, an etch selectivity, or any combination thereof.

In one embodiment, a flowable layer is deposited over a plurality of features over a substrate. Species are implanted to the flowable layer to increase a density of the flowable layer. A temperature of the species is adjusted to control the density of the flowable layer.

In one embodiment, a flowable layer is deposited over a plurality of features over a substrate. The plurality of features comprises a fin structure. A protection layer is deposited over the fin structure. Species are implanted to the flowable layer to increase a density of the flowable layer. A temperature of the species is adjusted to control the density of the flowable layer.

In one embodiment, a flowable layer is deposited over a plurality of features over a substrate. The flowable layer is oxidized. Species are implanted to the flowable layer to increase a density of the flowable layer. A temperature of the species is adjusted to control the density of the flowable layer.

In one embodiment, a flowable layer is deposited over a plurality of features over a substrate. The plurality of features comprises a hard mask feature. Species are implanted to the flowable layer to increase a density of the flowable layer. A temperature of the species is adjusted to control the density of the flowable layer. The hard mask feature is selectively removed.

In one embodiment, a flowable layer is deposited over a plurality of features over a substrate. Species are implanted to the flowable layer to increase a density of the flowable layer. A temperature of the species is adjusted to control the density of the flowable layer. At least one of an energy, a dose and a mass of the species is adjusted to control the density of the flowable layer.

In one embodiment, a flowable layer is deposited over a plurality of features over a substrate. Species are implanted to the flowable layer to increase a density of the flowable layer. A temperature of the species is adjusted to control the density of the flowable layer. The flowable layer is an oxide layer, a nitride layer, a carbide layer, or any combination thereof.

In one embodiment, a flowable layer is deposited over a plurality of features over a substrate. Species are implanted to the flowable layer to increase a density of the flowable layer. A temperature of the species is adjusted to control the density of the flowable layer. The species comprise silicon, germanium, hydrogen, boron, carbon, oxygen, nitrogen, argon, helium, neon, krypton, xenon, radon, arsenic, phosphorous, or any combination thereof.

In one embodiment, an apparatus to manufacture an electronic device comprises a processing chamber. The processing chamber comprises a pedestal to hold a workpiece comprising a flowable layer over a substrate. An ion source is coupled to the chamber and to an electromagnet system to supply species to the flowable layer. A processor is coupled to the ion source. The processor has a first configuration to modify a property of the flowable layer by controlling of implanting the species to the flowable layer. The property comprises a density, a stress, a film shrinkage, an etch selectivity, or any combination thereof.

In one embodiment, an apparatus to manufacture an electronic device comprises a processing chamber. The processing chamber comprises a pedestal to hold a workpiece comprising a flowable layer over a substrate. The flowable layer acts as an insulation fill layer, a hard mask layer, or both. An ion source is coupled to the chamber and to an electromagnet system to supply species to the flowable layer. A processor is coupled to the ion source. The processor has a first configuration to modify a property of the flowable layer by controlling of implanting the species to the flowable layer. The property comprises a density, a stress, a film shrinkage, an etch selectivity, or any combination thereof.

In one embodiment, an apparatus to manufacture an electronic device comprises a processing chamber. The processing chamber comprises a pedestal to hold a workpiece comprising a flowable layer over a substrate. An ion source is coupled to the chamber and to an electromagnet system to supply species to the flowable layer. A processor is coupled to the ion source. The processor has a first configuration to modify a property of the flowable layer by controlling of implanting the species to the flowable layer. The property comprises a density, a stress, a film shrinkage, an etch selectivity, or any combination thereof. The processor has a second configuration to adjust at least one of a temperature, an energy, a dose and a mass of the species to control the property of the flowable layer.

In one embodiment, an apparatus to manufacture an electronic device comprises a processing chamber. The processing chamber comprises a pedestal to hold a workpiece comprising a flowable layer over a substrate. An ion source is coupled to the chamber and to an electromagnet system to supply species to the flowable layer. The species comprise silicon, germanium, hydrogen, boron, carbon, oxygen, nitrogen, argon, helium, neon, krypton, xenon, radon, arsenic, phosphorous, or any combination thereof. A processor is coupled to the ion source. The processor has a first configuration to modify a property of the flowable layer by controlling of implanting the species to the flowable layer. The property comprises a density, a stress, a film shrinkage, an etch selectivity, or any combination thereof.

In one embodiment, an apparatus to manufacture an electronic device comprises a processing chamber. The processing chamber comprises a pedestal to hold a workpiece comprising a flowable layer over a substrate. An ion source is coupled to the chamber and to an electromagnet system to supply species to the flowable layer. A processor is coupled to the ion source. The processor has a first configuration to modify a property of the flowable layer by controlling of implanting the species to the flowable layer. The property comprises a density, a stress, a film shrinkage, an etch selectivity, or any combination thereof. The processor has a third configuration to control oxidizing the flowable layer. The processor has a fourth configuration to control removing at least a portion of the modified flowable layer.

In one embodiment, an apparatus to manufacture an electronic device comprises a processing chamber. The processing chamber comprises a pedestal to hold a workpiece comprising a flowable layer deposited over a patterned hard mask layer over a substrate. An ion source is coupled to the chamber and to an electromagnet system to supply species to the flowable layer. A processor is coupled to the ion source. The processor has a first configuration to modify a property of the flowable layer by controlling of implanting the species to the flowable layer. The property comprises a density, a stress, a film shrinkage, an etch selectivity, or any combination thereof. The processor has a fifth configuration to control removing of the patterned hard mask layer while leaving portions of the modified flowable layer intact.

In one embodiment, an apparatus to manufacture an electronic device comprises a processing chamber. The processing chamber comprises a pedestal to hold a workpiece comprising a flowable layer deposited over a plurality of features over a substrate. An ion source is coupled to the chamber and to an electromagnet system to implant species to the flowable layer to increase a density of the flowable layer. A processor is coupled to the ion source. The processor has a first configuration to adjust a temperature of the species to control the density of the flowable layer.

In one embodiment, an apparatus to manufacture an electronic device comprises a processing chamber. The processing chamber comprises a pedestal to hold a workpiece comprising a flowable layer deposited over a plurality of features over a substrate. The plurality of features comprises a fin structure. A protection layer is deposited over the fin structure. An ion source is coupled to the chamber and to an electromagnet system to implant species to the flowable layer to increase a density of the flowable layer. A processor is coupled to the ion source. The processor has a first configuration to adjust a temperature of the species to control the density of the flowable layer.

In one embodiment, an apparatus to manufacture an electronic device comprises a processing chamber. The processing chamber comprises a pedestal to hold a workpiece comprising a flowable layer deposited over a plurality of features over a substrate. An ion source is coupled to the chamber and to an electromagnet system to implant species to the flowable layer to increase a density of the flowable layer. A processor is coupled to the ion source. The processor has a first configuration to control oxidizing the flowable layer. The processor has a second configuration to adjust a temperature of the species to control the density of the flowable layer.

In one embodiment, an apparatus to manufacture an electronic device comprises a processing chamber. The processing chamber comprises a pedestal to hold a workpiece comprising a flowable layer deposited over a plurality of features over a substrate. The plurality of features comprises a hard mask feature. An ion source is coupled to the chamber and to an electromagnet system to implant species to the flowable layer to increase a density of the flowable layer. A processor is coupled to the ion source. The processor has a first configuration to adjust a temperature of the species to control the density of the flowable layer. The processor has a third configuration to control selectively removing of the hard mask feature.

In one embodiment, an apparatus to manufacture an electronic device comprises a processing chamber. The processing chamber comprises a pedestal to hold a workpiece comprising a flowable layer deposited over a plurality of features over a substrate. An ion source is coupled to the chamber and to an electromagnet system to implant species to the flowable layer to increase a density of the flowable layer. A processor is coupled to the ion source. The processor has a first configuration to adjust a temperature of the species to control the density of the flowable layer. The processor has a fourth configuration to adjust at least one of an energy, a dose and a mass of the species to control the density of the flowable layer.

In one embodiment, an apparatus to manufacture an electronic device comprises a processing chamber. The processing chamber comprises a pedestal to hold a workpiece comprising a flowable layer deposited over a plurality of features over a substrate. The flowable layer is an oxide layer, a nitride layer, a carbide layer, or any combination thereof. An ion source is coupled to the chamber and to an electromagnet system to implant species to the flowable layer to increase a density of the flowable layer. A processor is coupled to the ion source. The processor has a first configuration to adjust a temperature of the species to control the density of the flowable layer.

In one embodiment, an apparatus to manufacture an electronic device comprises a processing chamber. The processing chamber comprises a pedestal to hold a workpiece comprising a flowable layer deposited over a plurality of features over a substrate. An ion source is coupled to the chamber and to an electromagnet system to implant species to the flowable layer to increase a density of the flowable layer. The species comprise silicon, germanium, hydrogen, boron, carbon, oxygen, nitrogen, argon, helium, neon, krypton, xenon, radon, arsenic, phosphorous, or any combination thereof. A processor is coupled to the ion source. The processor has a first configuration to adjust a temperature of the species to control the density of the flowable layer.

Other features of the present invention will be apparent from the accompanying drawings and from the detailed description which follows.

### BRIEF DESCRIPTION OF THE DRAWINGS

The embodiments as described herein are illustrated by way of example and not limitation in the figures of the accompanying drawings in which like references indicate similar elements.

FIG. 1A shows a side view of an electronic device structure to form insulating regions according to one embodiment of the invention.

FIG. 1B is a view similar to FIG. 1A after a flowable layer is deposited over the features of the device layer according to one embodiment of the invention.

FIG. 1C is a view similar to FIG. 1B illustrating oxidizing the flowable layer according to one embodiment of the invention.

FIG. 1D is a view similar to FIG. 1C illustrating implanting species to the flowable layer according to one embodiment of the invention.

FIG. 1E is a view similar to FIG. 1D after a portion of the flowable layer modified by implanting species is removed according to one embodiment of the invention.

FIG. 1F is a view similar to FIG. 1E after upper portions of the features modified by implanting species are removed according to one embodiment of the invention.

FIG. 1G is a view similar to FIG. 1F after re-growth portions are deposited on the remaining portions of the features according to one embodiment of the invention.

FIG. 2A is a side view of an electronic device structure to form a mask according to one embodiment of the invention.

FIG. 2B is a view similar to FIG. 2A after a flowable layer is deposited into the trenches between features of a patterned hard mask layer according to one embodiment of the invention.

FIG. 2C is a view similar to FIG. 2B illustrating implanting species to the flowable layer according to one embodiment of the invention.

FIG. 2D is a view similar to FIG. 2C after the features of the hard mask layer are removed according to one embodiment of the invention.

FIG. 2E is a view similar to FIG. 2D after a device layer is etched using portions of the flowable layer as a hard mask according to one embodiment of the invention.

FIG. 2F is a view similar to FIG. 2E after one or more features of the hard mask layer are removed according to one embodiment of the invention.

FIG. 3A is a side view of an electronic device structure to form an electrode according to one embodiment of the invention.

FIG. 3B is a view similar to FIG. 3A after a portion of the flowable layer is modified by implanting species according to one embodiment of the invention.

FIG. 3C is a view similar to FIG. 3B after dummy electrodes are removed according to one embodiment of the invention.

FIG. 3D is a view similar to FIG. 3C after actual gate electrodes are deposited into the trenches according to one embodiment of the invention.

FIG. 3E is a view similar to FIG. 3D after the portions of the modified flowable layer are removed according to one embodiment of the invention.

FIG. 4 is a perspective view of a tri-gate transistor structure according to one embodiment of the invention.

FIG. 5A is a side view of an electronic device structure to form insulating regions according to another embodiment of the invention.

FIG. 5B is a view similar to FIG. 5A after re-growth portions are formed on device features according to another embodiment of the invention.

FIG. 5C is a view similar to FIG. 5B after a second flowable layer modified by species is deposited on top and sidewalls of the re-growth portions according to one embodiment of the invention.

FIG. 5D is a view similar to FIG. 5C after a portion of the flowable layer modified by implanting the species is removed according to one embodiment.

FIG. 6 shows images after etching of a FCVD dielectric layer in a dense pattern area and in an open (ISO) area according to one embodiment of the invention.

FIG. 7 shows graphs illustrating tuning properties of a FCVD silicon dioxide film by implantation according to one embodiment of the invention.

FIG. 8 shows graphs illustrating Secondary Ion Mass Spectroscopy (SIMS) modeling of different implant species according to one embodiment of the invention.

FIG. 9 shows a block diagram of one embodiment of a processing system to modify a characteristic of a flowable layer by implantation according to one embodiment of the invention.

### DETAILED DESCRIPTION

In the following description, numerous specific details, such as specific materials, chemistries, dimensions of the elements, etc. are set forth in order to provide thorough understanding of one or more of the embodiments of the present invention. It will be apparent, however, to one of ordinary skill in the art that the one or more embodiments of the present invention may be practiced without these specific details. In other instances, semiconductor fabrication processes, techniques, materials, equipment, etc., have not been described in great details to avoid unnecessarily obscuring of this description. Those of ordinary skill in the art, with the included description, will be able to implement appropriate functionality without undue experimentation.

While certain exemplary embodiments of the invention are described and shown in the accompanying drawings, it is to be understood that such embodiments are merely illustrative and not restrictive of the current invention, and that this invention is not restricted to the specific constructions and arrangements shown and described because modifications may occur to those ordinarily skilled in the art.

Reference throughout the specification to “one embodiment”, “another embodiment”, or “an embodiment” means that a particular feature, structure, or characteristic described in connection with the embodiment is included in at least one embodiment of the present invention. Thus, the appearance of the phrases “in one embodiment” or “in an embodiment” in various places throughout the specification are not necessarily all referring to the same embodiment. Furthermore, the particular features, structures, or characteristics may be combined in any suitable manner in one or more embodiments.

Moreover, inventive aspects lie in less than all the features of a single disclosed embodiment. Thus, the claims following the Detailed Description are hereby expressly incorporated into this Detailed Description, with each claim standing on its own as a separate embodiment of this invention. While the invention has been described in terms of several embodiments, those skilled in the art will recognize that the invention is not limited to the embodiments described, but can be practiced with modification and alteration within the spirit and scope of the appended claims. The description is thus to be regarded as illustrative rather than limiting.

Methods and apparatuses to tune a property of a flowable layer to manufacture an electronic device are described. Generally, a flowable material refers to a self-compacting material having a flowable consitensy that is used as a fill or backfill material. Typically, the flowable material is deposited to conform with the underlying layer topology, e.g., to fill openings in the underlying layer, e.g., trenches, cracks, holes, voids, slots, pits, and other openings.

In one embodiment, species are supplied to a flowable layer over a substrate. A property of the flowable layer is modified by implanting the species to the flowable layer. The property comprises a density, a stress, etch resistance, an etch selectivity, or any combination thereof. In an embodiment, species comprise ionized atoms, ionized molecules, clusters of ions, other ionized particles, or any combination thereof.

An implantation process to treat the flowable layer as described herein provides an advantage as it improves density of the flowable layer deposited over the substrate, reduces the flowable layer stress, and improves the etch resistance and etch selectivity between different films comparing with the existing flowable layer curing techniques. The flowable layer is modified by implanting the species so that the uniformity of the local density and the uniformity of the local etch selectivity along the flowable layer are increased.

Moreover, by selecting implant species and an implant condition the chemical composition of the flowable layer is advantageously fine tuned to provide a new property (e.g., density, stress, an etch selectivity, or any combination thereof) to the flowable layer. Fine tuning of the property of the flowable layer using the implantation process advantageously broadens the flowable layer application. For example, modifying the property of the flowable layer by implanting the species can advantageously reverse tone patterning in a patterning scheme to relax the overlay requirement as described in further detail below. In an embodiment, modifying the property of the flowable layer using the implantation process advantageously eliminates the pattern loading effect, as described in further detail below.

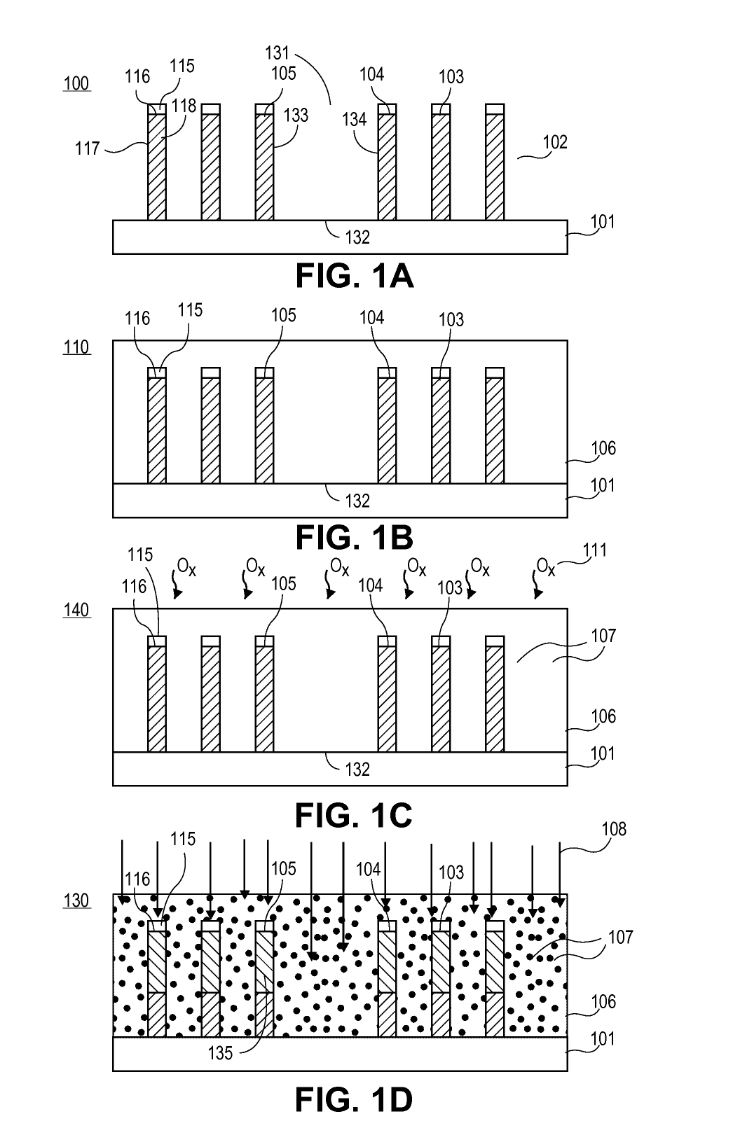

FIG. 1A shows a side view of an electronic device structure 100 to form insulating regions according to one embodiment. Electronic device structure 100 comprises a substrate. In an embodiment, substrate 101 comprises a semiconductor material, e.g., silicon (“Si”), germanium (“Ge”), silicon germanium (“SiGe”), a III-V material based material, or any combination thereof. In one embodiment, substrate 101 includes metallization interconnect layers for integrated circuits. In one embodiment, substrate 101 includes electronic devices, e.g., transistors, memories, capacitors, resistors, optoelectronic devices, switches, and any other active and passive electronic devices that are separated by an electrically insulating layer, for example, an interlayer dielectric, a trench insulation layer, or any other insulating layer known to one of ordinary skill in the art of the electronic device manufacturing. In at least some embodiments, substrate 101 includes interconnects, for example, vias, configured to connect the metallization layers. In one embodiment, substrate 101 is a semiconductor-on-isolator (SOI) substrate including a bulk lower substrate, a middle insulation layer, and a top monocrystalline layer. The top monocrystalline layer may comprise any material listed above, e.g., silicon.

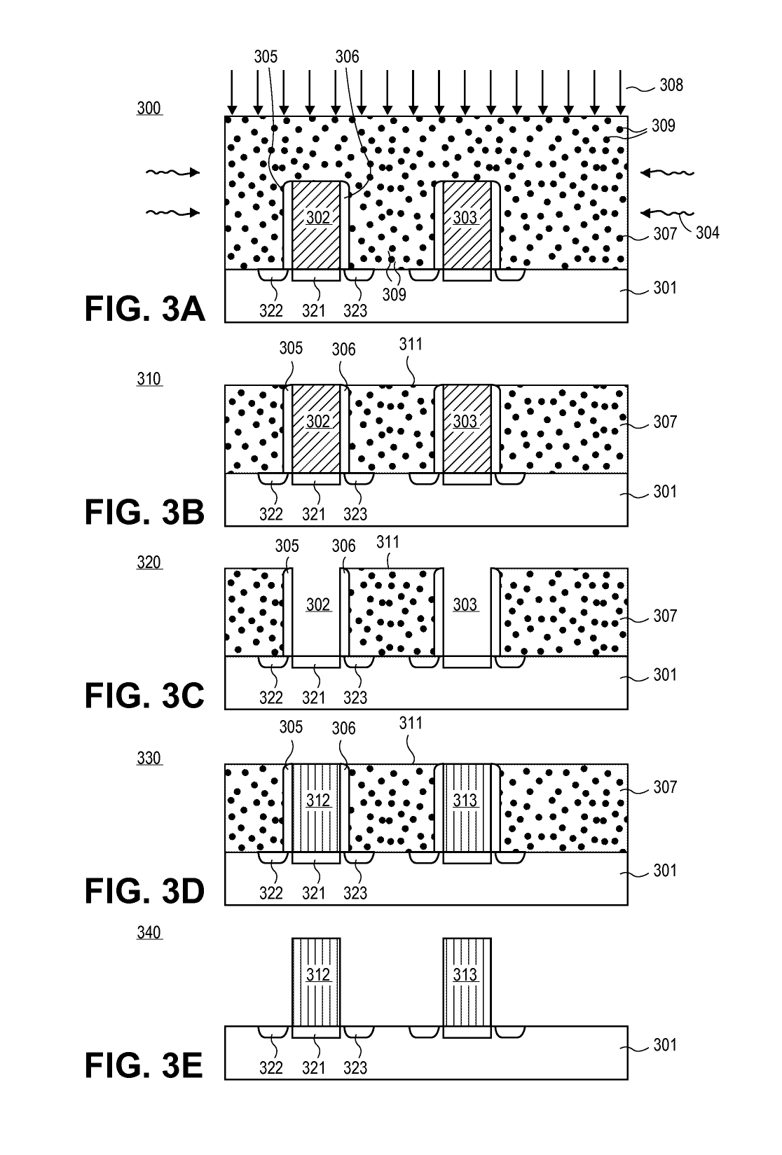

A device layer 102 is deposited on substrate 101. In an embodiment, device layer 102 comprises a plurality of features, such as features 103, 104 and 105. As shown in FIG. 1A, a plurality of trenches, such as a trench 131 are formed on substrate 101 between the features. Trench has a bottom portion 132 and opposing sidewalls 133 and 134. Bottom portion 132 is an exposed portion of the substrate 101 between the features 104 and 105. A sidewall 133 is the sidewall of the feature 105, and a sidewall 134 is the sidewall of the feature 104. In an embodiment, the device layer 102 includes one or more semiconductor fins formed on the substrate 101. In an embodiment, the features, e.g., 103, 104 and 105 are fin structures to form, for example, a tri-gate transistor array including multiple transistors, such as a transistor 400 shown in FIG. 4.

In an embodiment, the height of the features 103, 104 and 105 is in an approximate range from about 30 nm to about 500 nm (μm). In an embodiment, the distance between the features 103 and 104 is from about 2 nm to about 100 nm.

In an embodiment, device layer 102 comprises one or more layers deposited on substrate 101 using one or more deposition techniques, such as but not limited to a chemical vapor deposition (“CVD”), e.g., a Plasma Enhanced Chemical Vapor Deposition (“PECVD”), a physical vapor deposition (“PVD”), molecular beam epitaxy (“MBE”), metalorganic chemical vapor deposition (“MOCVD”), atomic layer deposition (“ALD”), or other deposition techniques known to one of ordinary skill in the art of electronic device manufacturing. In an embodiment, the one or more layers of the device layer 102 are patterned and etched using patterning and etching techniques known to one of ordinary skill in the art of electronic device manufacturing to form features, such as features 103, 104 and 105. In an embodiment, each of the features of the device layer 102 is a stack of one or more layers. In an embodiment, the features of the device layer 102 are features of electronic devices, e.g., transistors, memories, capacitors, resistors, optoelectronic devices, switches, and any other active and passive electronic devices.

In an embodiment, the features of the device layer 102 comprise a semiconductor material layer, e.g., Si, Ge, SiGe, a III-V material based material layer, e.g., GaAs, InSb, GaP, GaSb based materials, carbon nanotubes based materials, or any combination thereof. In one embodiment, the features of the device layer 102 comprise an insulating layer, e.g., an oxide layer, such as silicon oxide, aluminum oxide (“Al₂O₃”), silicon oxide nitride (“SiON”), a silicon nitride layer, other electrically insulating layer determined by an electronic device design, or any combination thereof. In one embodiment, the features of the device layer 102 comprise polyimide, epoxy, photodefinable materials, such as benzocyclobutene (BCB), and WPR-series materials, or spin-on-glass.

In an embodiment, the features of the device layer 102 comprise a conductive layer. In an embodiment, the features of the device layer 102 comprise a metal, for example, copper (Cu), aluminum (Al), indium (In), tin (Sn), lead (Pb), silver (Ag), antimony (Sb), bismuth (Bi), zinc (Zn), cadmium (Cd), gold (Au), ruthenium (Ru), nickel (Ni), cobalt (Co), chromium (Cr), iron (Fe), manganese (Mn), titanium (Ti), hafnium (Hf), tantalum (Ta), tungsten (W), vanadium (V), molybdenum (Mo), palladium (Pd), gold (Au), platinum (Pt), polysilicon, other conductive layer known to one of ordinary skill in the art of electronic device manufacturing, or any combination thereof.

As shown in FIG. 1A, a protection layer 115 is optionally deposited over the features of the device layer 102. The protection layer 115 covers top portions, such as a top portion 116 of each of the features of the device layer 105, as shown in FIG. 1A. The protection layer 115 is deposited to protect the features of the device layer 102 from processing at a later stage. In an embodiment, the features of the device layer 105 are silicon features. In one embodiment, the protection layer 115 is a hard mask layer. In another embodiment, the protection layer covers the top portions and sidewalls, such as a sidewall 117 and a sidewall 118 of each of the features of the device layer 105. In one embodiment, the protection layer 115 is a nitride layer, e.g., silicon nitride, titanium nitride, an oxide layer, e.g., a boron oxide layer, a boron doped glass layer, a silicon oxide layer, other protection layer, or any combination thereof. In an embodiment, the thickness of the protection layer 115 is from about 2 nm to about −50 nm.

The protection layer 115 can be deposited using one or more deposition techniques, such as but not limited to a chemical vapor deposition (“CVD”), e.g., a Plasma Enhanced Chemical Vapor Deposition (“PECVD”), a physical vapor deposition (“PVD”), molecular beam epitaxy (“MBE”), metalorganic chemical vapor deposition (“MOCVD”), atomic layer deposition (“ALD”), or other deposition techniques known to one of ordinary skill in the art of electronic device manufacturing.

FIG. 1B is a view 110 similar to FIG. 1A after a flowable layer 106 is deposited over the features of the device layer 102. As shown in FIG. 1B, flowable layer 106 covers optional protection layer 115 deposited on top portions, sidewalls of the features of the device layer and bottom portions of the trenches, such as bottom portion 132. In another embodiment, flowable layer 106 is deposited directly on the top portions and sidewalls of the features of the device layer 102 without protection layer 115.

As shown in FIG. 1B, flowable layer 106 is deposited on portions of the substrate 101 filling in the space between the features of the device layer 102. In an embodiment, flowable layer 106 is a dielectric layer. In an embodiment, density of the flowable flowable layer 106 is less or about 1.5 g/cm³. Generally, the density of a material refers to the mass of the material per unit volume (mass divided by volume). In an embodiment, flowable layer 106 has pores (not shown). Generally, pores in the material refer to regions which contain something other than the considered material (e.g., air, vacuum, liquid, solid, or a gas or gaseous mixture) so that the density of the flowable layer varies depending on location.

In an embodiment, flowable layer 106 is an oxide layer, e.g., silicon oxide (e.g., SiO₂), aluminum oxide (“Al₂O₃”), or other oxide layer, a nitride layer, e.g., silicon nitride (e.g., Si₃N₄), or other nitride layer, a carbide layer (e.g., carbon, SiOC), or other carbide layer, an oxide nitride layer, (e.g., SiON), or any combination thereof.

In an embodiment, flowable layer 106 is a flowable CVD film developed as a non-carbon containing film for sub 50 nm gap fill applications. In an embodiment, non-carbon containing Si molecule (e.g., TSA—trisilylamine) and NH3 are selected as precursors in deposition. NH3 is ionized through a plasma source (e.g., a remote plasma source). NHx* radicals are generated and react with Si—H bond in silicon precursor to form a polysilazane-type film. As-deposited film typically contains Si—H, Si—N, and —NH bonds. The film is then converted in an oxidizing environment to Si—O network through curing and annealing. In one embodiment, flowable layer 106 is a metallorganic precursor, a spin-on based material, or other flowable material.

In an embodiment, flowable layer 106 is deposited using one or more flowable chemical vapor deposition (“FCVD”) deposition techniques developed by Applied Materials, Inc. located in Santa Clara, Calif., or other FCVD technique.

In an embodiment, flowable layer 106 is deposited using one of deposition techniques, such as but not limited to a chemical vapor deposition (“CVD”), e.g., a Plasma Enhanced Chemical Vapor Deposition (“PECVD”), a physical vapor deposition (“PVD”), molecular beam epitaxy (“MBE”), metalorganic chemical vapor deposition (“MOCVD”), atomic layer deposition (“ALD”), or other deposition techniques known to one of ordinary skill in the art of electronic device manufacturing.

In an embodiment, the thickness of the flowable layer 106 is from about 30 nm to about 500 nm. In more specific embodiment, the thickness of the flowable layer 106 is from about 40 nm to about 100 nm.

In an embodiment, the flowable layer 106 acts as a gap fill layer. In an embodiment, flowable layer 106 acts as a gap fill layer over one portion of substrate, and acts as hard mask layer over other portion of substrate.

FIG. 1C is a view 130 similar to FIG. 1B illustrating oxidizing Ox 111 flowable layer 106 according to one embodiment. In an embodiment, the flowable layer 106 is oxidized by oxygen gas (O₂), ozone (O₃), or any combination thereof to form insulating regions between the features of the device layer 102. In an embodiment, the flowable layer 106 is oxidized by ozone at a temperature in an approximate range from about 100 degrees C. to about 200 degrees C., and in more specific embodiment, at about 145 degrees C. In an embodiment, the flowable layer 106 is treated by ozone to form shallow trench insulation (STI) regions. In an embodiment, the flowable layer 106 of FCVD silicon dioxide is treated with ozone (O₃), oxygen (O₂) gas ambient, or both at temperature from about 25 degrees C. to 500 degrees C. In an embodiment, the flowable layer 106 is cured by oxygen using one of oxygen curing techniques known to one of ordinary skill in the art of electronic device manufacturing. In an embodiment, flowable layer 106 is oxidized before being treated by implantation of species. In alternative embodiment, flowable layer 106 is oxidized after being treated by implantation of species.

FIG. 1D is a view 140 similar to FIG. 1C illustrating implanting 108 species 107 to the flowable layer 106 according to one embodiment of the invention. Species, such as species 107 are supplied to the flowable layer 106, as shown in FIG. 1D. In an embodiment, the species 107 comprise ionized atoms, ionized molecules, clusters of ions, other ionized particles, or any combination thereof.

In an embodiment, the species 107 comprise silicon, germanium, boron, carbon, hydrogen, oxygen, nitrogen, argon, helium, neon, krypton, xenon, radon, arsenic, phosphorus, or any combination thereof. As shown in FIG. 1D, the species 107 are implanted into the flowable layer 106. Upper portions of the features, such as an upper portion 135, are modified by the species. In an embodiment, the species 107 convert a crystalline material of the upper portions of the features 104 and 105 into an amorphous material. In more specific embodiment, the species 107 convert the upper portions of the silicon features into amorphous silicon portions. In another embodiment, the features of the device layer 102 are protected from the species by protection layer 115. In an embodiment, a temperature of the species is increased from a room temperature Tᵣₒₒₘ to a temperature Tₕₒₜ ensure that the features of the device layer 102 are not damaged by the species. In an embodiment, the room temperature Tᵣₒₒₘ is from about 20 degrees C. to about 35 degrees C. In an embodiment, the increased temperature Tₕₒₜ is in an approximate range from about in an approximate range from about 100 degrees C. to about 550 degrees C. (and in more specific embodiment, is about 350 degrees C.). The species 107 are implanted to eliminate the pores and increase density of the flowable layer 106.

A property of the flowable layer 106 is modified by implanting species to the flowable layer. In an embodiment, the flowable layer property modified by the implantation is a density, a stress, a film shrinkage, an etch selectivity, or any combination thereof. In an embodiment, implanting the species 107 increases the flowable layer density. In an embodiment, implanting the species 107 decreases the flowable layer stress. In an embodiment, implanting the species 107 increases uniformity of the etch selectivity of the flowable layer. In an embodiment, implanting the species 107 increases the flowable layer etch resistance.

In an embodiment, one or more parameters of the species, such as a temperature, energy, a dose, a mass, or any combination thereof are adjusted to control the flowable layer property. In an embodiment, the temperature of the species 107 is increased to control the flowable layer density.

In an embodiment, the species 107 comprising silicon and oxygen are implanted into the FCVD SiO2 layer to increase the layer density and reduce stress. In an embodiment, the species 107 comprising silicon and oxygen are implanted into the FCVD SiO2 layer to increase the layer density and reduce stress. In an embodiment, the temperature of the species 107 is in an approximate range from about 20 degrees C. to about 550 degrees C. In an embodiment, the dose of each of the species 107 comprising silicon and oxygen is an approximate range from about 1E16 (1×10̂15) to about 1E22 (1×10̂21) atoms/cm². In an embodiment, by changing the implant species temperature and dose, the flowable dielectric film density is increased from about 1.5 to about 2.25. In an embodiment, treatment of the flowable film by the ion implantation process increases the film density, etch resistance and reduces the film stress, film thickness shrinkage compared to a standard steam anneal treatment. Furthermore, the stress of the flowable layer is tunable by selecting the implanted species chemistry, mass, temperature and dose. Moreover, the chemical composition of the flowable layer can be changed by selecting a chemistry of the implant species. For example, other species (e.g. implant carbon) can be added to silicon and oxygen implants to change the FCVD SiO2 chemical composition to obtain desired film properties.

In one embodiment, one or more implantation operations are used to adjust the property of the flowable film 106. In an embodiment, the species comprising silicon, oxygen and argon are implanted into the FCVD SiO2 dielectric layer by a plurality of implantation operations at different conditions. For example, at a first implantation operation silicon ions are supplied to the FCVD SiO2 dielectric layer at energy from about 20 keV to about 40 keV (and in more specific embodiment, at about 30 keV) and dose from about 1×10̂16 atoms/cm² to about 1×10̂17 atoms/cm² (and in more specific embodiment, at about 5×10̂16 atoms/cm²); oxygen ions are supplied to the FCVD SiO2 dielectric layer at energy from about 10 keV to about 30 keV (and in more specific embodiment, at about 20 keV) and dose from about 1×10̂16 atoms/cm² to about 1×10̂17 atoms/cm² (and in more specific embodiment, at about 5×10̂16 atoms/cm²); argon ions are supplied to the FCVD SiO2 dielectric layer at energy from about 40 keV to about 60 keV (and in more specific embodiment, at about 50 keV) and dose from about 1×10̂16 atoms/cm² to about 1×10̂17 atoms/cm² (and in more specific embodiment, at about 5×10̂16 atoms/cm²). For example, at a second implantation operation silicon ions are supplied to the FCVD SiO2 dielectric layer at energy from about 5 keV to about 10 keV (and in more specific embodiment, at about 7 keV) and dose from about 5×10̂15 atoms/cm² to about 5×10̂16 atoms/cm² (and in more specific embodiment, at about 1×10̂16 atoms/cm²); oxygen ions are supplied to the FCVD SiO2 dielectric layer at energy from about 2 keV to about 6 keV (and in more specific embodiment, at about 4 keV) and dose from about 5×10̂15 atoms/cm² to about 5×10̂16 atoms/cm² (and in more specific embodiment, at about 1×10̂16 atoms/cm²); argon ions are supplied to the FCVD SiO2 dielectric layer at energy from about 8 keV to about 12 keV (and in more specific embodiment, at about 10 keV) and dose from about 5×10̂15 atoms/cm² to about 5×10̂16 atoms/cm² (and in more specific embodiment, at about 1×10̂16 atoms/cm²). In one embodiment, the species 107 are implanted to the flowable layer 106 at a room temperature (e.g., from about 20 degrees C. to about 35 degrees C.). In one embodiment, the species 107 are implanted to the flowable layer 106 at a temperature higher than the room temperature (e.g., in an approximate range from about 40 degrees C. to about 550 degrees C.) to avoid damage of the underlying features of the device layer 102. In one embodiment, the species 107 are implanted to the flowable layer 106 at a temperature lower than the room temperature (e.g., in an approximate range from about minus 100 degrees C. to about 20 degrees C.).

FIG. 1E is a view 150 similar to FIG. 1D after a portion of the flowable layer modified by implanting species is removed according to one embodiment. As shown in FIG. 1E, the protection layer 115 and the modified flowable layer 106 are removed from the top portions of the features 103, 104 and 105. As shown in FIG. 1E, portions of the flowable layer 106 such as a portion 109 fill the space between the device features, such as features 103, 104 and 105.

In an embodiment, the modified flowable layer 106 and protection layer 115 are removed from the top of the features of the device layer 102 using one of a chemical-mechanical polishing (CMP) techniques known to one of ordinary skill in the art of electronic device manufacturing. In an embodiment, the protection layer 115 and the modified flowable layer 106 are wet etched to a predetermined depth using one of wet etching techniques, or other etching techniques known to one of ordinary skill in the art of electronic device manufacturing.

FIG. 1F is a view 160 similar to FIG. 1E after upper portions of the features modified by implanting species are removed according to one embodiment of the invention. As shown in FIG. 1F, the modified upper portion 135 of the feature 105 is removed to form a trench 136. Trench 136 has a bottom portion 137 and opposing sidewalls 138 and 139. Bottom portion 137 comprises the remaining unmodified portion of the feature 105. The sidewall 138 is a part of the sidewall of the modified portion 141 of the flowable layer 106. The sidewall 139 is a part of the sidewall of the modified portion 109 of the flowable layer.

In an embodiment, the modified portions of the features 103, 104, and 105 are removed by selective etching using a plasma chemistry which has a substantially high selectivity over the remaining layers. In an embodiment, the modified portions of the features 103, 104, and 105 are selectively etched using a plasma etching technique, or other selective etching technique known to one of ordinary skill in the art of electronic device manufacturing.

FIG. 1G is a view 170 similar to FIG. 1F after re-growth portions are deposited on the remaining portions of the features according to one embodiment of the invention. As shown in FIG. 1G, a re-growth portion 142 is formed on the remaining portion of the feature 105 and a re-growth portion 143 is formed on the remaining portion of the feature 104.

In one embodiment, the re-growth portions comprise the material different from the material of the device features. For a non-limiting example, feature 105 is silicon, and re-growth portion 142 is silicon germanium. In another embodiment, the re-growth portions comprise the same material as the material of the features. For a non-limiting example, feature 105 is silicon, and re-growth portion 142 is silicon. The re-growth portions can be formed on features using one or more re-growth techniques known to one of ordinary skill in the art of electronic device manufacturing.

In an embodiment, re-growth portion 142 is a part of the underlying device feature 105. In another embodiment, re-growth portion 142 is a part of another device feature. In an embodiment, the re-growth portions 142 and 143 represent the device features described above with respect to FIG. 1A.

As shown in FIG. 1G, the flowable layer 106 modified by the species is deposited on portions of the substrate 101 to insulate adjacent device features 103, 104 and 105 and prevent leakage. The modified flowable dielectric layer 106 has increased k-value and decreased leakage comparing with the standard dielectric layer. As shown in FIG. 1G, the modified flowable layer 106 is used as a STI trench fill.

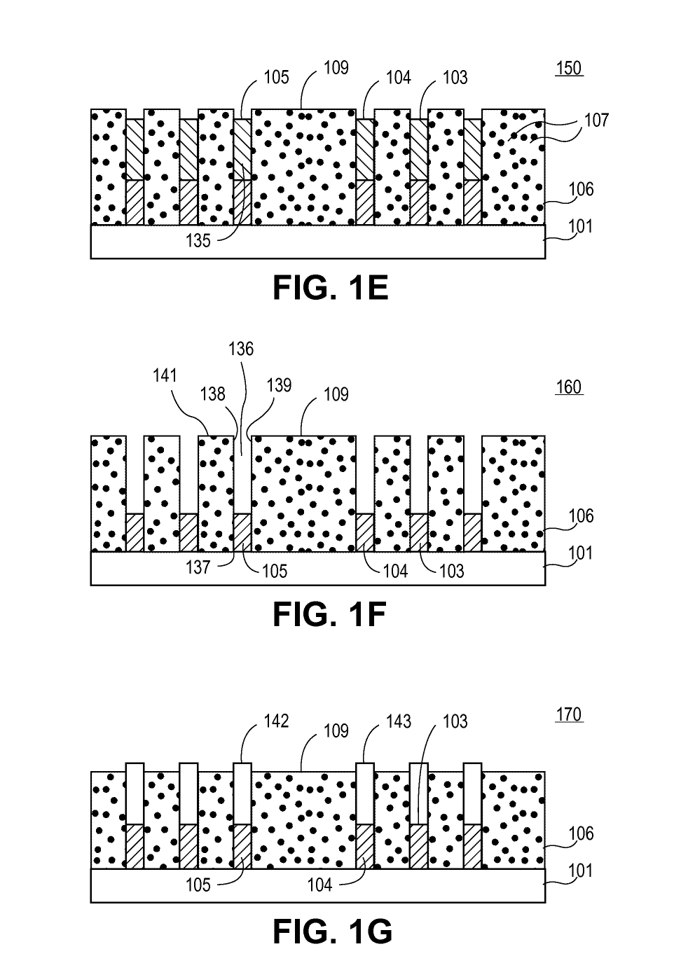

FIG. 2A is a side view of an electronic device structure 200 to form a mask according to one embodiment. Electronic device structure 200 comprises a substrate 201. The substrate 201 is represented by substrate 101. An etch stoplayer 202 is deposited on substrate 201. In one embodiment, the etch stop layer 202 comprises an insulating layer, e.g., an oxide layer, such as titanium oxide (TiO2), titanium nitride (TiN), silicon oxide, aluminum oxide (“Al2O3”), silicon oxide nitride (“SiON”), a silicon nitride layer, other electrically insulating layer determined by an electronic device design, or any combination thereof. In one embodiment, the etch stop layer 202 comprises polyimide, epoxy, photodefinable materials, such as benzocyclobutene (BCB), and WPR-series materials, or spin-on-glass.

The etch stop layer 202 can be deposited on substrate 201 using one or more deposition techniques, such as but not limited to a chemical vapor deposition (“CVD”), e.g., a Plasma Enhanced Chemical Vapor Deposition (“PECVD”), a physical vapor deposition (“PVD”), molecular beam epitaxy (“MBE”), metalorganic chemical vapor deposition (“MOCVD”), atomic layer deposition (“ALD”), or other deposition techniques known to one of ordinary skill in the art of electronic device manufacturing.

A patterned hard mask layer 203 comprising a plurality of features 204, 206, 205, and 207 is deposited on etch stop layer 202. The features 204, 206, 205, and 207 are separated by trenches, such as a trench 251 and a trench 252, as shown in FIG. 2A. As shown in FIG. 2A, sidewall spacers—e.g., a sidewall spacer 221 and a sidewall spacer 222—are formed on opposing sidewalls of each of the features. In an embodiment, the material of the sidewall spacers is different from the material of the features. In an embodiment, each of the features comprises a dielectric material, e.g., silicon oxide, silicon nitride, silicon carbide, or other dielectric material. In an embodiment, each of the sidewall spacers comprises a dielectric material, e.g., silicon oxide, silicon nitride, silicon carbide, or any other spacer material known to one of ordinary skill in the art of electronic device manufacturing. In more specific embodiment, the feature comprises silicon oxide, the sidewall spacers sidewall spacers deposited thereon comprise silicon nitride. In another more specific embodiment, the feature comprises silicon nitride and the sidewall spacers sidewall spacers deposited thereon comprise silicon oxide. The sidewall spacers can be formed by depositing a spacer layer (not shown) on the features 204, 206, 205, and 207 and then etching the spacer layer, as known one of ordinary skill in the art of electronic device manufacturing.

In an embodiment, the height of each of the features 204, 206, 205, and 207 is in an approximate range from about 30 nm to about 500 nm. In an embodiment, the distance between the features 204, 206, 205 and 207 is from about 5 nm to about 100 nm.

In one embodiment, a hard mask layer deposited over etch stop layer 202 is patterned and etched to form the features using patterning and etching techniques known to one of ordinary skill in the art of electronic device manufacturing. In one embodiment, the features of the patterned hard mask layer 203 are made of the same material. In one embodiment, the features of the patterned hard mask layer 203 are made of different materials.

In an embodiment, the features 204, 205, 206 and 207 of the hard mask layer 203 are formed using a single lithography process and etch. In another embodiment, some features, such as features 204 and 205 are formed using one lithography process and etch, and other features, such as features 206 and 207 of the hard mask layer 203 are formed using another lithography process and etch.

FIG. 2B is a view 210 similar to FIG. 2A after a flowable layer 208 is deposited on the features 204, 205, 206 and 207 and into the trenches, such as trenches 251 and 252 between the features of the patterned hard mask layer 203 according to one embodiment of the invention. A plurality of flowable layer portions, such as portions 212 and 213 are formed between the features of the patterned hard mask layer 203. As shown in FIG. 2B, flowable layer 208 is deposited on portions of the etch stop layer 202 filling in the space between the features of the patterned hard mask layer 203. In an embodiment, flowable layer 208 is a dielectric layer, as described above with respect to flowable layer 106. In another embodiment, flowable layer 208 is a conductive layer, e.g., ruthenium oxide, or other flowable conductive layer.

In an embodiment, flowable layer 208 is an oxide layer, e.g., silicon oxide (e.g., Si_{O2}), aluminum oxide (“Al2O3”), or other oxide layer, a nitride layer, e.g., silicon nitride (e.g., S_{i3N4}), or other nitride layer, a carbide layer (e.g., carbon, SiOC), or other carbide layer, an oxide nitride layer, (e.g., SiON), or any combination thereof. In an embodiment, flowable layer 208 acts as a hard mask layer. In an embodiment, flowable layer 208 comprises material that is different from the material of the features and the material of the sidewall spacers.

In an embodiment, flowable layer 208 is deposited using one or more flowable chemical vapor deposition (“FCVD”) deposition techniques developed by Applied Materials, Inc. located in Santa Clara, Calif., or other FCVD technique.

In an embodiment, flowable layer 208 is deposited using one of deposition techniques, such as but not limited to a chemical vapor deposition (“CVD”), e.g., a Plasma Enhanced Chemical Vapor Deposition (“PECVD”), a physical vapor deposition (“PVD”), molecular beam epitaxy (“MBE”), metalorganic chemical vapor deposition (“MOCVD”), atomic layer deposition (“ALD”), or other deposition techniques known to one of ordinary skill in the art of electronic device manufacturing.

FIG. 2C is a view 220 similar to FIG. 2B illustrating implanting 209 species 211 to the flowable layer 208 according to one embodiment of the invention. Species, such as species 211 are supplied to the flowable layer 208, sidewall spacers 221, 222, and the features 204, 205, 206, and 207, as shown in FIG. 2C. In an embodiment, the species 211 comprise ionized atoms, ionized molecules, clusters of ions, other ionized particles, or any combination thereof.

In an embodiment, the species 211 comprise silicon, germanium, boron, carbon, hydrogen, oxygen, nitrogen, argon, helium, neon, krypton, xenon, radon, arsenic, phosphorus, or any combination thereof. As shown in FIG. 2C, the species 211 are implanted into the flowable layer 208, the sidewall spacers 221, 222, and the features 204, 205, 206, and 207. In one embodiment, the property of at least one of the flowable layer 208, the sidewall spacers 221, 222, and the features 204, 205, 206, and 207 is modified by implanting the species In an embodiment, the flowable layer 208 is modified by implanting the species, as described above with respect to flowable layer 106. In an embodiment, the species are implanted into the features 204, 205, 206, and 207, so that the material of the features is modified to have etching rate higher than the etching rate of the flowable layer 208 and the sidewall spacers. In an embodiment, the species are implanted into the sidewall spacers 221 and 222, so that the material of the sidewall spacers is modified to have etching rate higher than the etching rate of the flowable layer 208 and the etching rate of the features.

The chemistry of the species is selected and implant conditions (e.g., dose, energy, temperature) are optimized to achieve desired etch selectivity to remove a feature (e.g., feature 204), a portion of the flowable layer (e.g., portion 212), a sidewall spacer (e.g., sidewall spacer 222), or any combination thereof. In an embodiment, the chemistry of the species is selected and implantation conditions (e.g., dose, energy, temperature) are optimized to increase etch selectivity of the features 204, 205, 206, and 207 over the sidewall spacers (e.g., sidewall spacers 221 and 222), the portions of the flowable layer 208, etch stop layer 202, or any combination thereof. In another embodiment, the chemistry of the species is selected and implantation conditions (e.g., dose, energy, temperature) are optimized to increase etch selectivity of the sidewall spacers (e.g., sidewall spacers 221 and 222) over the features 204, 205, 206 and 207, the portions of the flowable layer 208, etch stop layer 202, or any combination thereof. In yet another embodiment, the chemistry of the species is selected and implantation conditions (e.g., dose, energy, temperature) are optimized to increase etch selectivity of the portions of the flowable layer 208 over the features 204, 205, 206 and 207, the sidewall spacers (e.g., sidewall spacers 221 and 222), etch stop layer 202, or any combination thereof. In an embodiment, one or more parameters of the species, such as a temperature, energy, a dose, a mass, or any combination thereof are adjusted to control the flowable layer property, as described above with respect to flowable layer 106.

FIG. 2D is a view 230 similar to FIG. 2C after portions of the modified flowable layer are removed according to one embodiment of the invention. As shown in FIG. 2D, the top surfaces of the flowable layer portions 212 and 213 are substantially evened out with the top surfaces of the features 204, 205, 206 and 207 and the sidewall spacers 221 and 222. In an embodiment, the portions of the flowable layer 208 are removed from the top portions of the features of the hard mask layer 203 and from the top portions of the sidewall spacers using one of the CMP techniques known to one of ordinary skill in the art of electronic device manufacturing.

FIG. 2E is a view 240 similar to FIG. 2D after a patterned mask layer is formed on the features according to one embodiment of the invention. The patterned mask layer comprises a photoresist layer 225 on a hard mask layer 224 deposited on the top portions of the sidewall spacers, such as sidewall spacers 221 and 222, the top portions of the features 204, 205, 206, 207 and the top portions the modified flowable layer, such as portions 212 and 213. An opening 226 formed through the photoresist layer 225 and the hard mask layer 224 to expose the modified portions 212 and 213 of the flowable layer 106, the top portions of the sidewall spacers and the feature 206.

In an embodiment, the hard mask layer 224 comprises an organic hard mask. In an embodiment, the hard mask layer 224 comprises an amorphous carbon layer doped with a chemical element (e.g., boron, silicon, aluminum, gallium, indium, or other chemical element). In an embodiment, hard mask layer 224 comprises a boron doped amorphous carbon layer (“BACL”). In an embodiment, hard mask layer 224 comprises an aluminum oxide (e.g., Al₂O₃); polysilicon, amorphous Silicon, poly germanium (“Ge”), a refractory metal (e.g., tungsten (“W”), molybdenum (“Mo”), other refractory metal, or any combination thereof.

FIG. 2F is a view 250 similar to FIG. 2E after one or more features of the hard mask layer 203 are removed according to one embodiment of the invention. Feature 206 is removed by selective etching. The feature 206 is selectively etched through opening 226 to expose a portion of the etch stop layer 202. Portions 212 and 213 of the modified flowable layer 208 and sidewall spacers 227 and 228 are left intact by etching. The etch selectivity of the feature 206 over the portions of the modified flowable layer and the sidewall spacers is increased by implantation, as described above. Increasing the etch selectivity by implantation relaxes the photoresist alignment requirement, so that the size of the opening 226 in the photoresist layer 240 and hard mask layer 224 can be greater than the size 232 of the removed feature 206, as shown in FIGS. 2E and 2F.

In an embodiment, etch resistance of the flowable layer 208 modified by implanting the species is increased comparing with the standard flowable layer etch resistance, as described above. As shown in FIG. 2F, because of the increased etch resistance, the portions of the modified flowable layer 208, such as portions 212 and 213 are not affected by etch of the feature 204 203. In an embodiment, the one or more features of the hard mask layer 203 are removed using one of plasma etching techniques, or other dry etching techniques known to one of ordinary skill in the art of electronic device manufacturing.

FIG. 2E is a view 240 similar to FIG. 2D after a etch stop layer 202 is etched using the portions, such as portions 213 and 212 of the flowable layer 208 as a hard mask according to one embodiment of the invention. As shown in FIG. 2E, the etch stop layer 202 is etched through the portions of the flowable layer down to substrate 201 to form a plurality of device features, such as a device feature 215 and a device feature 215. That is, the treatment of the flowable layer 208 by implanting species is used in a patterning scheme, e.g., reverse tone hard mask formation. The portions of the modified flowable layer 208 above the device features 215 and 216 are removed using one of plasma etching techniques, or other dry or wet etching technique known to one of ordinary skill in the art of electronic device manufacturing.

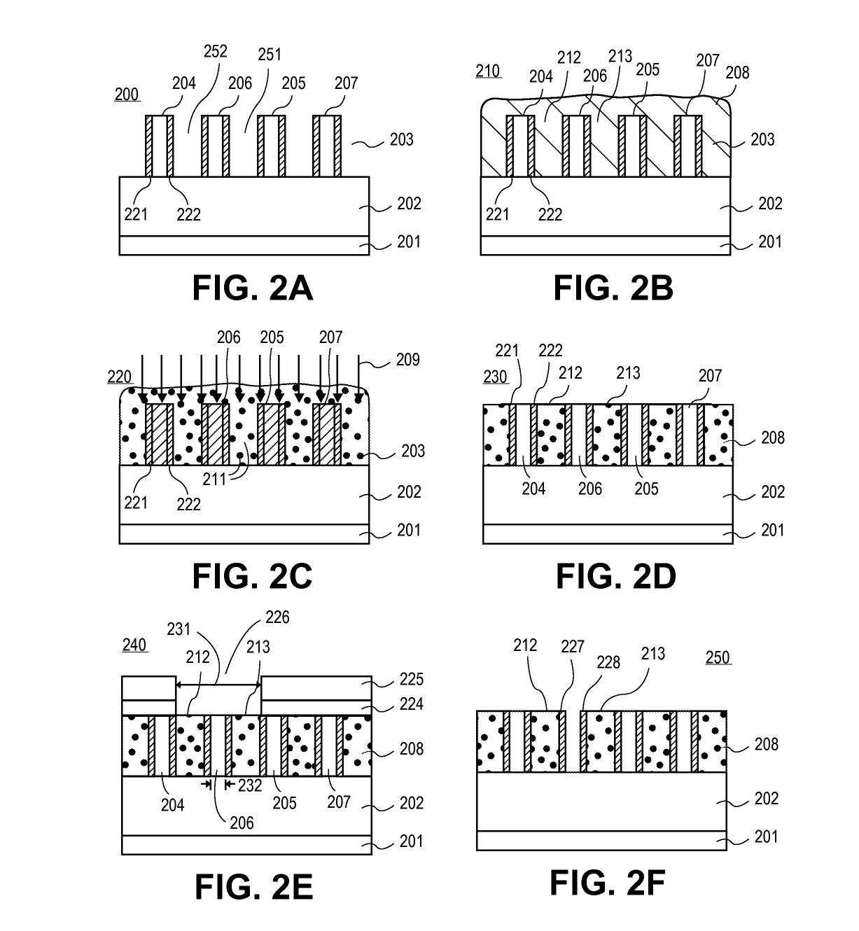

FIG. 3A is a side view of an electronic device structure 300 to form an electrode according to one embodiment. Electronic device structure 300 comprises a fin layer 301. In an embodiment, fin layer 301 comprises a device layer on a substrate. The substrate represents one of the substrates 101 and 201. The device layer represents one of the device layers 102 and 202. In an embodiment, fin layer 301 is used to form a tri-gate transistor array including multiple transistors.

A plurality of dummy gate electrodes, such as a dummy gate electrode 302 and a dummy gate electrode 303 are formed on fin layer 301. The dummy gate electrodes can be formed of any suitable dummy gate electrode material. In an embodiment, the dummy gate electrodes 302 and 303 comprise polycrystalline silicon. In an embodiment, a gate dielectric, such as a gate dielectric 321 is deposited underneath the dummy gate electrode 302 on fin layer 301. The gate dielectric layer can be any well-known gate dielectric layer. In another embodiment, the dummy gate electrode is deposited directly on the fin layer 301. In one embodiment, source and drain regions, such as a source region 322 and a drain region 323 are formed on fin layer 301 at opposite sides of each of the dummy gate electrodes. In another embodiment, the dummy gate electrode is deposited on the fin layer that does not have the drain and source regions formed thereon.

The portion of the fin layer 301 located between the source region and drain regions typically defines a channel region of the transistor. The channel region can also be defined as the area of the fin surrounded by the gate electrode. The source and drain regions can be formed using any source and drain forming techniques known to one of ordinary skill in the art of electronic device manufacturing.

FIG. 4 is a perspective view of a tri-gate transistor structure 400 according to one embodiment. A fin layer comprising a fin 402 is formed on a substrate 401. In an embodiment, fin layer 301 represents a cross-sectional view of the fin 402 along A-A¹ axis. In an embodiment, tri-gate transistor 400 is a part of a tri-gate transistor array that includes multiple tri-gate transistors. In an embodiment, the flowable dielectric layer modified by implanting species is formed on substrate 401 adjacent to fin 402 to provide field isolation (e.g., STI) regions that isolate one electronic device from other devices on substrate 401, as described above with respect to FIGS. 1A-1E.

As shown in FIG. 4, the fin 402 protrudes from a top surface of the substrate 401. Fin 402 can be formed of any well-known semiconductor material, such as but not limited to silicon (Si), germanium (Ge), silicon germanium (Siₓ Ge_{y}), gallium arsenide (GaAs), InSb, GaP, GaSb and carbon nanotubes. A gate dielectric layer (not shown) is deposited on and around three sides of the fin 402. The gate dielectric layer is formed on the opposing sidewalls and on the top surface of the fin 402. As shown in FIG. 4, a gate electrode 406 is deposited on the gate dielectric layer on the fin 402. Gate electrode 406 is formed on and around the gate dielectric layer on the fin 402 as shown in FIG. 4. A drain region 405 and a source region 403 are formed at opposite sides of the gate electrode 406 in fin 402, as shown in FIG. 4. In an embodiment, source region 322 represents source region 403 and drain region 323 represents drain region 405.

Referring back to FIG. 3A, spacers, such as a spacer 305 and a spacer 306 are deposited on the sidewalls of the dummy gate electrodes. The spacers can be formed on the dummy gate electrodes using any of spacer forming techniques known to one of ordinary skill in the art of electronic device manufacturing. In an embodiment, spacers 305 and 306 comprise a nitride material, e.g., silicon nitride, or any other spacer material known to one of ordinary skill in the art of electronic device manufacturing.

A dielectric layer 307 is deposited over the dummy electrodes on fin layer 301. Dielectric layer 307 represents one of the dielectric layer 107 and dielectric layer 208. Species, such as species 309 are supplied to the dielectric layer 307, as shown in FIG. 3A. Species 309 represent one of species 107 and 211. In an embodiment, dielectric layer 307 is oxidized before being treated by implantation of species. In another embodiment, dielectric layer 307 is oxidized after being treated by implantation of species.

As shown in FIG. 3A, the species 309 are implanted into the dielectric layer 307. As shown in FIG. 3A, the spacers on the dummy electrodes 302 and 303, such as spacers 305 and 306 are left substantially free of the species. In an embodiment, a temperature 304 of the species is increased from a room temperature Tᵣₒₒₘ to a temperature Tₕₒₜ prevent damage of the spacers by the species, as described above with respect to FIG. 1D. The property of the dielectric layer 307 is modified by implanting species 309, as described above.

FIG. 3B is a view 310 similar to FIG. 3A after a portion of the dielectric layer 307 modified by implanting species is removed according to one embodiment. As shown in FIG. 3B, the portion of the modified dielectric layer 307 above the dummy electrodes 302 and 303 is removed. The portions of the modified dielectric layer 307 adjacent to and covering the spacers, such as spacers 305 and 306 are left intact. As shown in FIG. 3B, the top surfaces of the portions of the dielectric layer 307 are substantially evened out with the top surfaces of the dummy gate electrodes 302 and 303. In an embodiment, the portion of modified dielectric layer 106 is removed from the tops of the dummy gate electrodes using one of a chemical-mechanical polishing (CMP) techniques known to one of ordinary skill in the art of electronic device manufacturing.

FIG. 3C is a view 320 similar to FIG. 3B after the dummy electrodes 302 and 303 are removed according to one embodiment of the invention. The dummy gate electrodes 302 and 303 are removed to expose portions of the fin layer 301, as shown in FIG. 3C. As described above, etch resistance of the modified dielectric layer 307 is increased comparing with the standard dielectric layer etch resistance. As shown in FIG. 3C, the portions of the modified dielectric layer 307 adjacent to the spacers, such as a portion 311 are left intact by etch of the dummy electrodes, so that trenches 332 and 333 are formed between the spacers. The portions of the modified dielectric layer adjacent to the spacers advantageously prevent the spacers from collapsing during removal of the dummy electrodes. In an embodiment, the dummy gate electrodes 302 and 303 are removed using one of plasma etching techniques, or other dry or wet etching techniques known to one of ordinary skill in the art of electronic device manufacturing.

FIG. 3D is a view 330 similar to FIG. 3C after actual gate electrodes are deposited into the trenches between the spacers according to one embodiment of the invention. As shown in FIG. 3D, actual gate electrodes, such as a gate electrode 312 and 313 are formed on the portions of the fin layer 301 between the spacers. The actual gate electrodes can be formed of any suitable gate electrode material. In an embodiment, the gate electrode can be a metal gate electrode, such as but not limited to, tungsten, tantalum, titanium, and their nitrides. It is to be appreciated, the gate electrode 104 need not necessarily be a single material and can be a composite stack of thin films, such as but not limited to a polycrystalline silicon/metal electrode or a metal/polycrystalline silicon electrode. The gate electrodes 312 and 313 can be deposited on the fin layer using one or more gate electrode deposition techniques known to one of ordinary skill in the art of electronic device manufacturing.

FIG. 3E is a view 340 similar to FIG. 3D after the portions of the modified dielectric layer 307 are removed from fin layer 301 according to one embodiment. As shown in FIG. 3E, the spacers are removed from the sidewalls of the actual gate electrodes 312 and 313. In an embodiment, the portions of the modified dielectric layer 307 and the spacers are removed by etching using one of plasma etching techniques, or other dry etching technique known to one of ordinary skill in the art of electronic device manufacturing. In an embodiment, gate electrode 406 represents one of the actual gate electrodes 312 and 313.

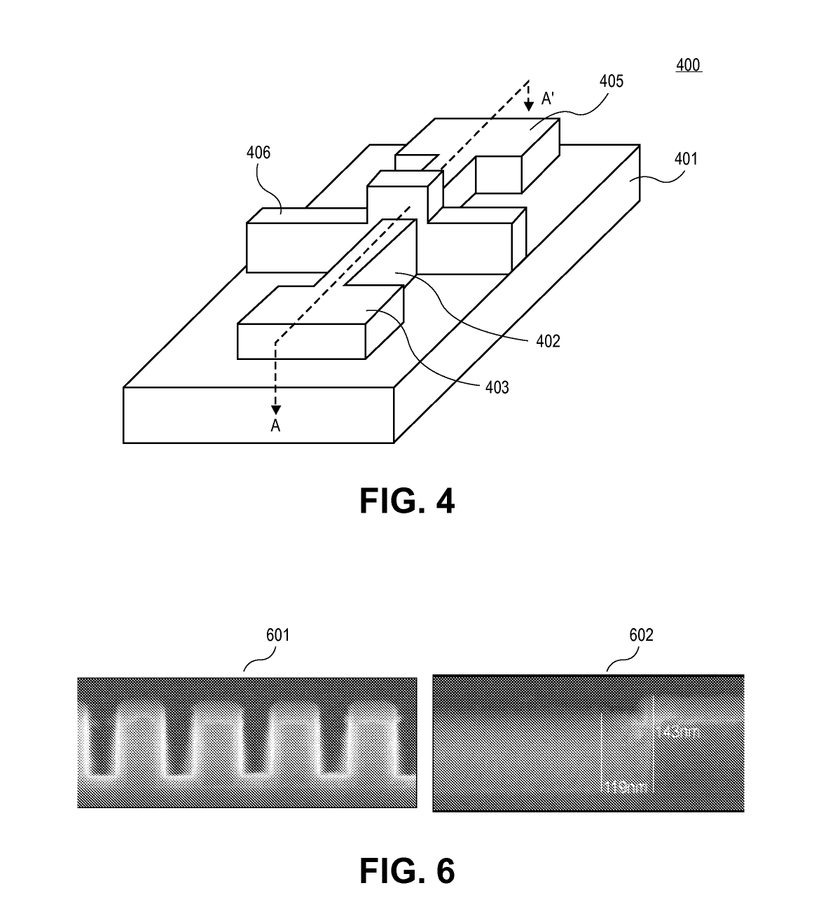

FIG. 5A is a side view of an electronic device structure 500 to form insulating regions according to another embodiment. Electronic device structure comprises a substrate 501. Substrate 501 represents one of the substrates described above. Device features, such as a device feature 502 and a device feature 503 are formed on substrate. The device features 502 and 503 represent the device features described above with respect to FIG. 1A. A first dielectric layer 504 modified by implanting species is deposited on substrate 501 between the device features 503 and 504, as described above. The dielectric layer 504 represents one of the dielectric layers 106, 208 and 307. Species, such as species 507 are implanted into the dielectric layer 507, as described above. The species 507 represent one of the species 107, 211 and 309. In an embodiment, dielectric layer 504 is oxidized before being treated by implantation of species. In another embodiment, dielectric layer 504 is oxidized after being treated by implantation of species.

FIG. 5B is a view 510 similar to FIG. 5A after re-growth portions are formed on device features according to one embodiment of the invention. As shown in FIG. 5B, a re-growth portion 505 is formed on top of the device feature 502 and a re-growth portion 506 is formed on top of the device feature 502. The dielectric layer 504 modified by implanting species has increased density, etch selectivity and reduced stress comparing with standard dielectric layers, as described above. The modified dielectric layer 504 is not substantially affected by the re-growth process.

In an embodiment, re-growth portion 505 is a part of the underlying device feature 502. In another embodiment, re-growth portion 505 is a part of another device feature. In an embodiment, the re-growth portions 505 and 506 represent the device features described above with respect to FIG. 1A.

In an embodiment, the re-growth portions comprise the same material as the device features. For a non-limiting example, device feature 502 comprises silicon, and re-growth portion 505 comprises silicon. In another embodiment, the growth portions comprise the material different from the material of the device features. For a non-limiting example, device feature 502 comprises silicon, and re-growth portion 505 comprises germanium. The re-growth portions can be formed on device features using one or more re-growth techniques known to one of ordinary skill in the art of electronic device manufacturing.

FIG. 5C is a view 520 similar to FIG. 5B after a second dielectric layer 509 modified by species is deposited on top and sidewalls of the re-growth portions 505 and 506 and dielectric layer 506 according to one embodiment of the invention.

A property of the dielectric layer 509 is modified by implanting species 508, as described above. The dielectric layer 509 represents one of the dielectric layers 106, 208 and 307. Species, such as species 508 are implanted into the dielectric layer 509, as described above. The species 508 represent one of the species 107, 211, 309. In an embodiment, dielectric layer 509 is oxidized before being treated by implantation of species. In another embodiment, dielectric layer 509 is oxidized after being treated by implantation of species.

FIG. 5D is a view 530 similar to FIG. 5C after a portion of the dielectric layer 509 modified by implanting the species is removed according to one embodiment. As shown in FIG. 5D, the portions of the modified dielectric layer 509 and 506 are removed from the top and upper portions of the sidewalls of the features 515 and 516. As shown in FIG. 5, a device feature 515 comprises re-growth portion 505 on feature 502, and a device feature 516 comprises re-growth portion 506 on feature 503. As shown in FIG. 5D, the modified dielectric layer 517 comprising the modified dielectric layer 509 on the modified dielectric layer 506 fills a space 511 between the device features 515 and 516.

In an embodiment, a portion of the modified dielectric layer 517 is removed from the top of the device features 515 and 516 using one of a chemical-mechanical polishing (CMP) techniques known to one of ordinary skill in the art of electronic device manufacturing. In an embodiment, the modified dielectric layer 517 is etched to a predetermined depth using one of plasma etching techniques, or other dry etching techniques known to one of ordinary skill in the art of electronic device manufacturing. As shown in FIG. 5D, the dielectric layer 517 modified by the species is deposited on portions of the substrate 501 to insulate adjacent device features 515 and 516 and prevent leakage. The modified dielectric layer 517 has increased k-value and decreased leakage comparing with the standard dielectric layer. As shown in FIG. 5D, the modified dielectric layer 517 acts as a STI trench fill.

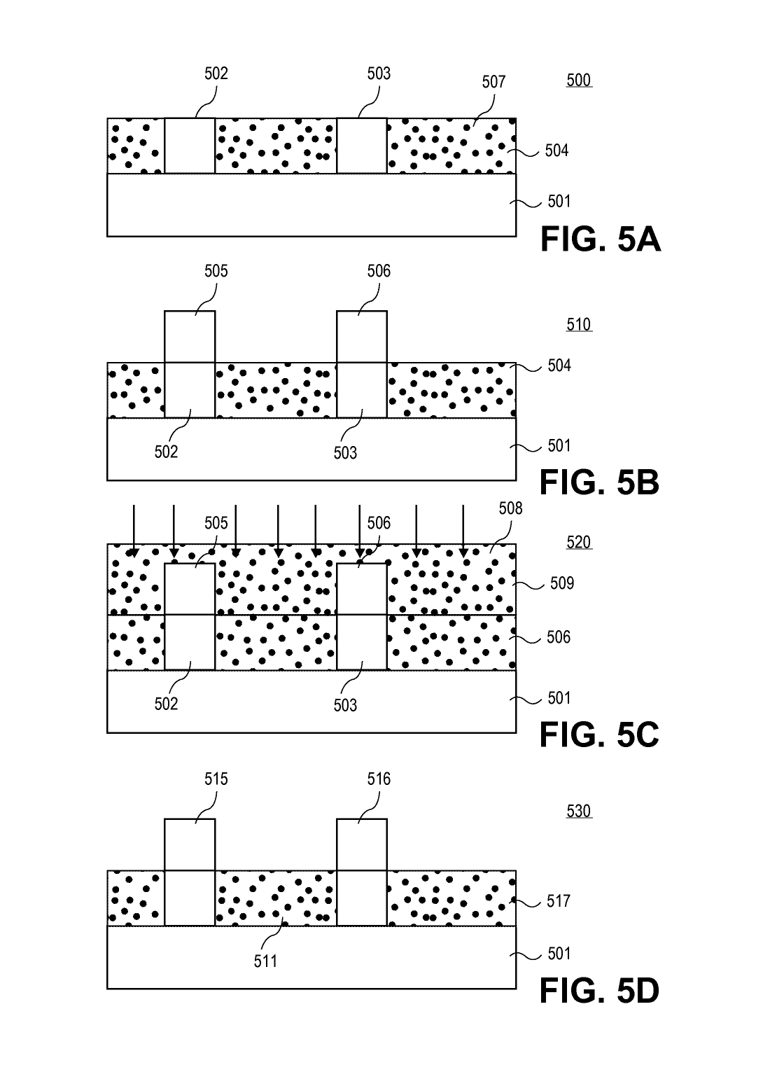

FIG. 6 shows images after etching of a FCVD dielectric layer in a dense pattern area 601 and in an open (ISO) area 602 according to one embodiment of the invention. Before etching, the FCVD dielectric layer has been treated using high temperature steam anneal. The high temperature steam anneal causes the shrinkage of the FCVD dielectric layer and high tensile stress. As shown in FIG. 6, the uneven quality of the FCVD dielectric layer causes dramatically different etch results in dense area 601 and ISO area 602.

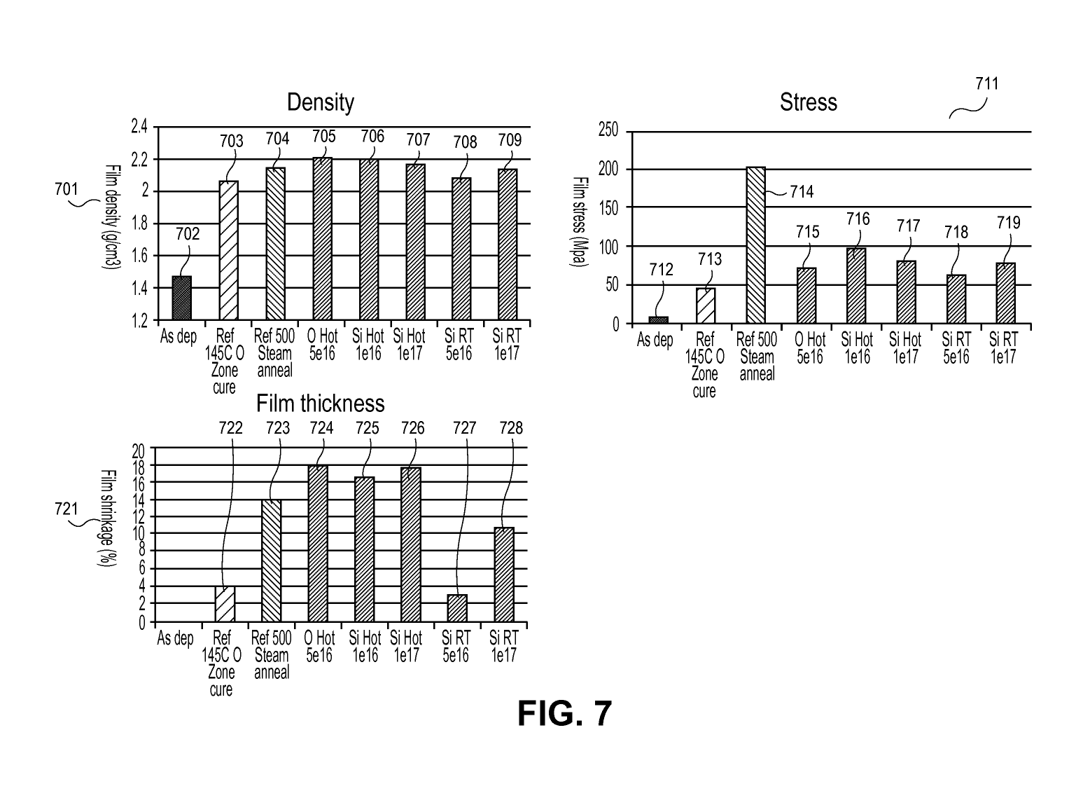

FIG. 7 shows graphs illustrating tuning properties of a FCVD silicon dioxide film by implantation according to one embodiment of the invention. A graph 701 shows an untreated FCVD silicon dioxide film density 702, the density of the FCVD silicon dioxide film cured by ozone at 145 degrees C. 703, the density of the FCVD silicon dioxide film cured by 500 degrees C. steam anneal 704, the density of the FCVD silicon dioxide film cured by implanting oxygen at a dose of 5×10̂16 atoms/cm̂2 at the temperature of 350 degrees C. (hot oxygen) 705, the density of the FCVD silicon dioxide film cured by implanting silicon at a dose of 5×10̂16 atoms/cm̂2 at the temperature of 350 degrees C. (hot silicon) 706; the density of the FCVD silicon dioxide film cured by implanting silicon at a dose of 5×10̂17 atoms/cm̂2 at the temperature of 350 degrees C. (hot silicon) 707; the density of the FCVD silicon dioxide film cured by implanting silicon at a dose of 5×10̂16 atoms/cm̂2 at a room temperature 708 and the density of the FCVD silicon dioxide film cured by implanting silicon at a dose of 5×10̂17 atoms/cm̂2 at a room temperature 709. As shown in graph 701, the density of the FCVD film after curing by implantation is increased in by about 5.5% to about 7.7% comparing with the untreated FCVD film. As shown in graph 701, the density increase is substantially independent of the dopant mass, dose, or both. A graph 711 shows the stress of an untreated FCVD silicon dioxide film density 712, the stress of the FCVD silicon dioxide film cured by ozone 713, the stress of the FCVD silicon dioxide film cured by 500 degrees C. steam anneal 714, the stress of the FCVD silicon dioxide film cured by implanting oxygen at a dose of 5×10̂16 atoms/cm̂2 at the temperature of 350 degrees C. (hot oxygen) 715, the stress of the FCVD silicon dioxide film cured by implanting silicon at a dose of 5×10̂16 atoms/cm̂2 at the temperature of 350 degrees C. (hot silicon) 716; the stress of the FCVD silicon dioxide film cured by implanting silicon at a dose of 5×10̂17 atoms/cm̂2 at the temperature of 350 degrees C. (hot silicon) 717; the stress of the FCVD silicon dioxide film cured by implanting silicon at a dose of 5×10̂16 atoms/cm̂2 at a room temperature 718 and the stress of the FCVD silicon dioxide film cured by implanting silicon at a dose of 5×10̂17 atoms/cm̂2 at a room temperature 719. As shown in graph 711, the stress of the film cured by the implants is smaller than the stress of the film treated by high temperature steam anneal. The stress of the film treated by implants depends on the mass of the implanted species, dose of the implanted species, or both. The stress of the film treated by the implant having smaller mass (e.g., oxygen) is smaller than the stress of the film treated by the implant having a greater mass (e.g., silicon). The stress of the film treated with the implant at higher dose is smaller than the stress of the film treated by the implant at a smaller dose. A graph 721 shows the shrinkage of the FCVD silicon dioxide film cured by ozone 722, the shrinkage of the FCVD silicon dioxide film cured by 500 degrees C. steam anneal 723, the shrinkage of the FCVD silicon dioxide film cured by implanting oxygen at a dose of 5×10̂16 atoms/cm̂2 at the temperature of 350 degrees C. (hot oxygen) 724, the shrinkage of the FCVD silicon dioxide film cured by implanting silicon at a dose of 5×10̂16 atoms/cm̂2 at the temperature of 350 degrees C. (hot silicon) 725; the shrinkage of the FCVD silicon dioxide film cured by implanting silicon at a dose of 5×10̂17 atoms/cm̂2 at the temperature of 350 degrees C. (hot silicon) 726; the shrinkage of the FCVD silicon dioxide film cured by implanting silicon at a dose of 5×10̂16 atoms/cm̂2 at a room temperature 727 and the shrinkage of the FCVD silicon dioxide film cured by implanting silicon at a dose of 5×10̂17 atoms/cm̂2 at a room temperature 728. As shown in graph 721, the film shrinkage increases for the films treated by hot implants comparing to the films treated by steam anneal. The film shrinkage decreases for the films treated by implants at room temperature comparing to the films treated by steam anneal.

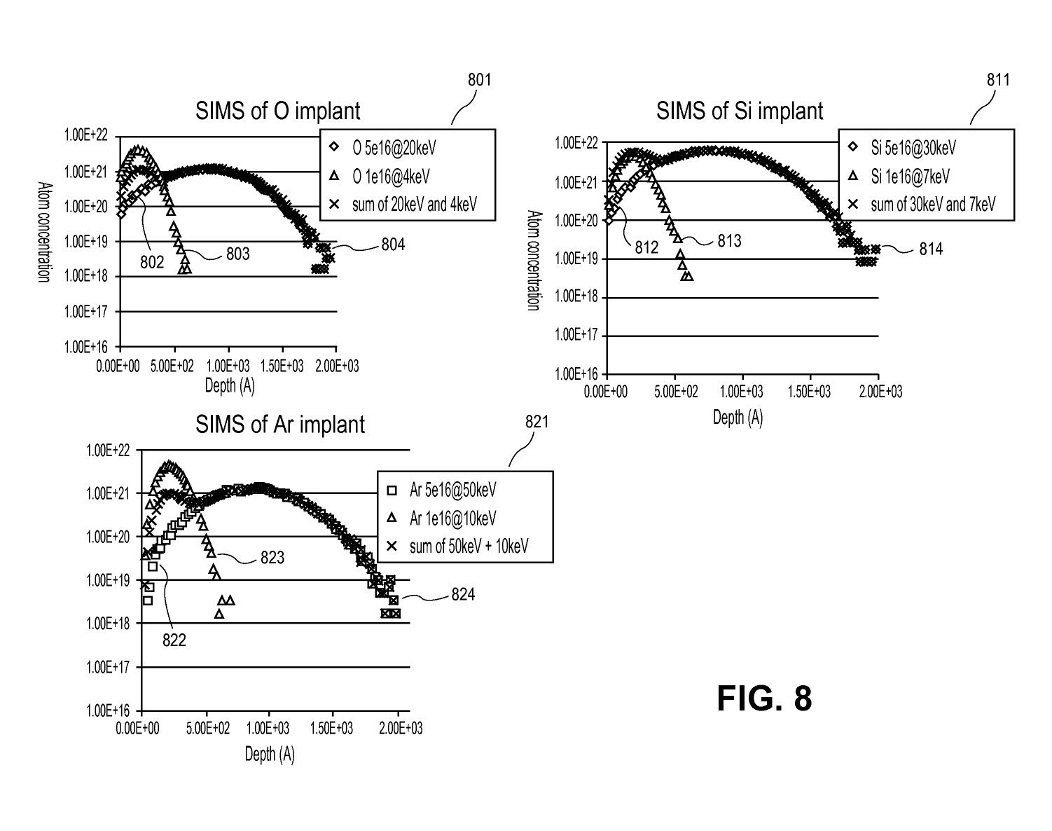

FIG. 8 shows graphs illustrating Secondary Ion Mass Spectroscopy (SIMS) modeling of different implant species according to one embodiment of the invention. A graph 801 shows an atom concentration versus depth of the FCVD silicon dioxide film for an oxygen implant at different implantation conditions. A curve 802 shows the atom concentration of the oxygen implant versus depth of the FCVD silicon dioxide film at a dose of 5×10̂16 atoms/cm̂2 and energy of 20 keV; a curve 803 shows the atom concentration of the oxygen implant versus depth of the FCVD silicon dioxide film at a dose of 10̂16 atoms/cm̂2 and energy of 4 keV; a curve 804 shows a sum of the curves 802 and 803. A graph 811 shows an atom concentration versus depth of the FCVD silicon dioxide film for a silicon implant at different implantation conditions. A curve 812 shows the atom concentration of the silicon implant versus depth of the FCVD silicon dioxide film at a dose of 5×10̂16 atoms/cm̂2 and energy of 30 keV; a curve 813 shows the atom concentration of silicon implant versus depth of the FCVD silicon dioxide film at a dose of 10̂16 atoms/cm̂2 and energy of 7 keV; a curve 814 shows a sum of the curves 812 and 813. A graph 821 shows an atom concentration versus depth of the FCVD silicon dioxide film for an argon implant at different implantation conditions. A curve 822 shows the atom concentration of the argon implant versus depth of the FCVD silicon dioxide film at a dose of 5×10̂16 atoms/cm̂2 and energy of 50 keV; a curve 823 shows the atom concentration of the argon implant versus depth of the FCVD silicon dioxide film at a dose of 10̂16 atoms/cm̂2 and energy of 10 keV; a curve 824 shows a sum of the curves 822 and 823. As shown in FIG. 8, a substantially uniform distribution of the implant species along the depth of the FCVD dielectric film is achieved by using multiple implantation operations at different implantation conditions (e.g., dose, energy, or both).

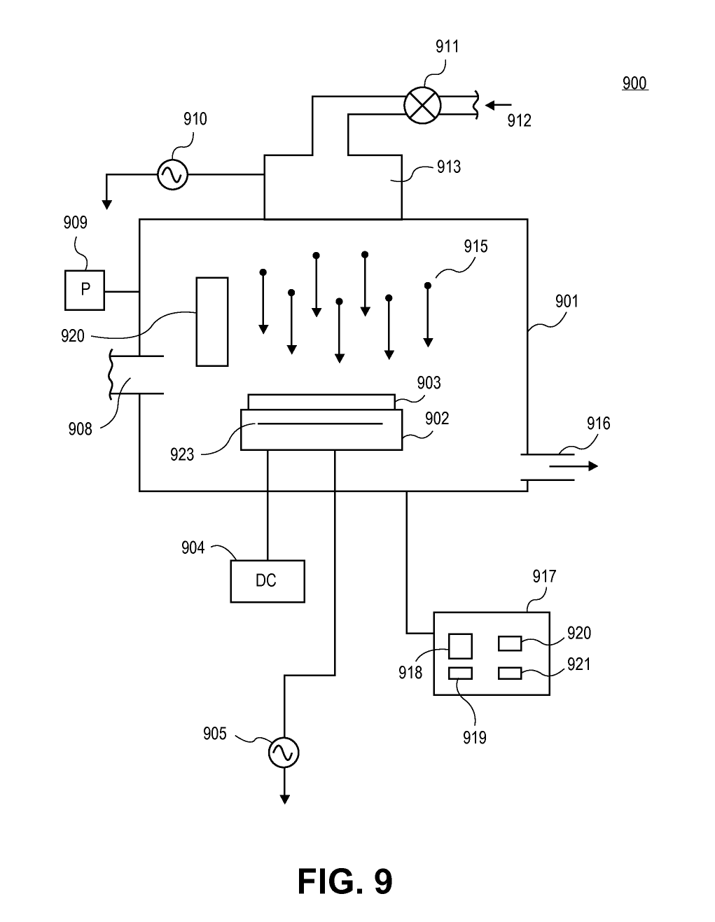

FIG. 9 shows a block diagram of one embodiment of a processing system 100 to modify a characteristic of a dielectric layer by implantation according to one embodiment of the invention. As shown in FIG. 9, system 900 has a processing chamber 901. A movable pedestal 902 to hold a workpiece 903 is placed in processing chamber 901. Pedestal 902 comprises an electrostatic chuck (“ESC”), a DC electrode embedded into the ESC, and a cooling/heating base. In an embodiment, the ESC comprises an Al₂O₃ material, Y₂O₃, or other ceramic materials known to one of ordinary skill of electronic device manufacturing. A DC power supply 104 is connected to the DC electrode of the pedestal 102.

As shown in FIG. 9, a workpiece 903 is loaded through an opening 908 and placed on the pedestal 902. In an embodiment, the workpiece comprises a dielectric layer over a substrate, as described above. An ion source 913 is coupled to processing chamber 901 and an electromagnet system 920. System 900 comprises an inlet 911 to receive one or more gases 912 and to supply the one or more gases to an ion source 913. Ion source 913 is coupled to processing chamber to generate species 915 from the one or more gases. Electromagnet system 920 is used to shape, steer and focus the species 915 for implantation into the dielectric layer, as described above. Ion source 913 is coupled to a source power 910. Species 915 comprise positive ions, e.g., ionized atoms, ionized molecules, clusters of ions, other ionized particles, or any combination thereof.

An electromagnet system power 905 is coupled to processing chamber 901. As shown in FIG. 9, a pressure control system 909 provides a pressure to processing chamber 901. As shown in FIG. 9, chamber 901 is evacuated via one or more exhaust outlets 916 to evacuate volatile products produced during processing in the chamber. A control system 917 is coupled to the chamber 901. The control system 917 comprises a processor 918, a temperature controller 919 coupled to the processor 918, a memory 920 coupled to the processor 918, and input/output devices 921 coupled to the processor 920. The processor has a first configuration to modify a property of the dielectric layer by controlling of implanting the species to the dielectric layer. The property comprises a density, a stress, an etch selectivity, or any combination thereof, as described above. The processor has a second configuration to adjust at least one of a temperature, an energy, a dose and a mass of the species to control the property of the dielectric layer, as described above. The processor has a third configuration to control oxidizing the dielectric layer, as described above. The processor has a fourth configuration to control removing at least a portion of the modified dielectric layer, as described above. The processor has a fifth configuration to control removing of the patterned hard mask layer while leaving portions of the modified dielectric layer intact. The control system 917 is configured to perform methods as described herein and may be either software or hardware or a combination of both. Memory 920 may include a machine-accessible storage medium (or more specifically a computer-readable storage medium) on which is stored one or more sets of instructions (e.g., software) embodying any one or more of the methodologies or functions described herein. The software may also reside, completely or at least partially, within the memory 920 and/or within the processor 918 during execution thereof by the the control system 917, the memory 920 and the processor 918 also constituting machine-readable storage media. The software may further be transmitted or received over a network (not shown) via a network interface device (not shown).

The processing system 100 may be any type of high performance semiconductor processing systems known in the art, such as but not limited to an ion implantation system, a plasma system, or any other species processing system to manufacture electronic devices. In an embodiment, the system 900 may represent one of the implant systems e.g., Beamline, Trident, Crion systems manufactured by Applied Materials, Inc. located in Santa Clara, Calif., or any other species processing system.

In the foregoing specification, embodiments of the invention have been described with reference to specific exemplary embodiments thereof. It will be evident that various modifications may be made thereto without departing from the broader spirit and scope of embodiments of the invention as set forth in the following claims. The specification and drawings are, accordingly, to be regarded in an illustrative sense rather than a restrictive sense.

What is claimed is:

1. A method to manufacture an electronic device comprising:
supplying species to a flowable layer over a substrate; and
adjusting a property of the flowable layer by implanting the species to the flowable layer, wherein the property comprises a density, a stress, a film shrinkage, an etch selectivity, or any combination thereof.

2. The method of claim 1, further comprising
adjusting at least one of a temperature, an energy, a dose and a mass of the species to control the property.

3. The method of claim 1, wherein the species comprise silicon, hydrogen, germanium, boron, carbon, oxygen, nitrogen, argon, helium, neon, krypton, xenon, radon, arsenic, phosphorus or any combination thereof.

4. The method of claim 1, further comprising
forming a plurality of fin structures on the substrate;
filling in the flowable layer between the fin structures;
and
removing at least a portion of the flowable layer.

5. The method of claim 1, further comprising
patterning a hard mask layer to form a plurality of trenches;
filling the flowable layer into the plurality of trenches; and
removing at least a portion of the patterned hard mask layer while leaving portions of the flowable layer intact, wherein the mask layer is modified by implanting the species to increase the etch selectivity.

6. The method of claim 1, further comprising
oxidizing the flowable layer.

7. The method of claim 1, wherein the flowable layer acts as an insulation layer, a hard mask layer, or both.

8. A method to manufacture an electronic device comprising:
depositing a flowable layer over a plurality of features over a substrate;
implanting species to the flowable layer over the plurality of features to adjust etch selectivity of at least one of the flowable layer and the plurality of features.

9. The method of claim 8, further comprising
adjusting a temperature of the species.

10. The method of claim 8, further comprising
oxidizing the flowable layer.

11. The method of claim 8 further comprising
forming sidewall spacers on the plurality of features;
selectively removing at least one of the plurality of features.

12. The method of claim 8, wherein further comprising
adjusting at least one of an energy, a dose and a mass of the species to control the etch selectivity.

13. The method of claim 8, wherein the flowable layer is an oxide layer, a nitride layer, a carbide layer, or any combination thereof.

14. The method of claim 8, wherein the species comprise silicon, hydrogen, germanium, boron, carbon, oxygen, nitrogen, argon, helium, neon, krypton, xenon, radon, arsenic, phosphorous or any combination thereof.

15. An apparatus to manufacture an electronic device comprising:
a processing chamber comprising a pedestal to hold a workpiece comprising a flowable layer over a substrate;
an ion source coupled to the processing chamber and an electromagnet system to supply species to the flowable layer;
a processor coupled to the ion source, wherein the processor has a first configuration to adjust a property of the flowable layer by controlling of implanting the species to the flowable layer, wherein the property comprises a density, a stress, a film shrinkage, an etch selectivity, or any combination thereof.

16. The apparatus of claim 15, wherein the dielectric layer acts as an isolation layer, a hard mask layer, or both.

17. The apparatus of claim 15, wherein the processor has a second configuration to adjust at least one of a temperature, an energy, a dose and a mass of the species to control the property.

18. The apparatus of claim 15, wherein the species comprise silicon, hydrogen, germanium, boron, carbon, oxygen, nitrogen, argon, helium, neon, krypton, xenon, radon, arsenic, phosphorous or any combination thereof.

19. The apparatus of claim 15, wherein the processor has a third configuration to control oxidizing the flowable layer, and wherein the processor has a fourth configuration to control removing at least a portion of the modified flowable layer.

20. The apparatus of claim 15, wherein the flowable layer is deposited over a patterned hard mask layer over the substrate, and the processor has a fifth configuration to control removing the patterned hard mask layer while leaving portions of the modified flowable layer intact.
